(19) United States
(12) Patent Application Publication
(10) Pub. No.: US 2019/0189447 A1
(43) Pub. Date: Jun. 20, 2019

(54) METHOD FOR FORMING SQUARE SPACERS

(71) Applicant: Lam Research Corporation, Fremont, CA (US)

(72) Inventors: Tom KAMP, San Jose, CA (US); Yoko YAMAGUCHI, Union City, CA (US)

(21) Appl. No.: 15/847,234

(22) Filed: Dec. 19, 2017

(51) Int. Cl. H01L 21/033; H01L 21/02; H01L 21/311; H01L 21/027; C23C 16/455; C23C 16/04; C23C 16/40; C23C 16/56

(52) U.S. Cl. CPC H01L 21/0338; H01J 37/321; H01L 21/0217; H01L 21/02274; H01L 21/0228; H01L 21/31116; H01L 21/31138; H01L 21/31144; H01L 21/0273; H01L 21/0332; H01L 21/0335; H01L 21/0337; C23C 16/45527; C23C 16/042; C23C 16/401; C23C 16/56; C23C 16/45536; H01L 21/02164

(57) ABSTRACT

A method for in-situ patterning a stack having a patterned mask with mask features including sidewalls and tops is provided. A plurality of patterning cycles is provided in a plasma chamber wherein each patterning cycle comprises: at least one (1) cycle of depositing an atomic layer deposition (ALD) over the mask features to create an ALD layer, wherein the ALD layer includes sidewalls over the sidewalls of the mask features and top portions over the tops of the mask features, and selectively etching the top portions of the ALD layer with respect to the sidewalls of the ALD layer.

### INCORPORATION BY REFERENCE

The present disclosure incorporates by reference for all purposes the US patent application entitled “INTEGRATED ATOMIC LAYER PASSIVATION IN TCP ETCH CHAMBER AND IN-SITU ETCH-ALP METHOD” by Zhou et al. filed on Aug. 4, 2017, U.S. application Ser. No. 15/669,871.

### BACKGROUND

The present disclosure relates to the formation of semiconductor devices. More specifically, the disclosure relates to the formation of semiconductor devices requiring etching features.

During semiconductor wafer processing, an intermediate layer below a patterned organic mask may be etched. Double or multiple patterning may be used to multiply the number of patterns in an area of the mask to increase the density of the pattern.

### SUMMARY

To achieve the foregoing and in accordance with the purpose of the present disclosure, a method for in-situ patterning a stack having a patterned mask with mask features including sidewalls and tops is provided. A plurality of patterning cycles is provided in a plasma chamber wherein each patterning cycle comprises: at least one (1) cycle of depositing an atomic layer deposition (ALD) over the mask features to create an ALD layer, wherein the ALD layer includes sidewalls over the sidewalls of the mask features and top portions over the tops of the mask features, and selectively etching the top portions of the ALD layer with respect to the sidewalls of the ALD layer.

These and other features will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of a process that may be used in an embodiment.

FIGS. 2A-F are schematic cross-sectional views of a stack processed according to an embodiment.

FIG. 3 is a schematic view of a plasma processing chamber that may be used in practicing an embodiment.

FIG. 4 illustrates a computer system, which is suitable for implementing a controller used in embodiments.

FIG. 5 is a more detailed flow chart of a cycle of depositing an ALD (atomic layer deposition) over the mask features.

### DETAILED DESCRIPTION

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

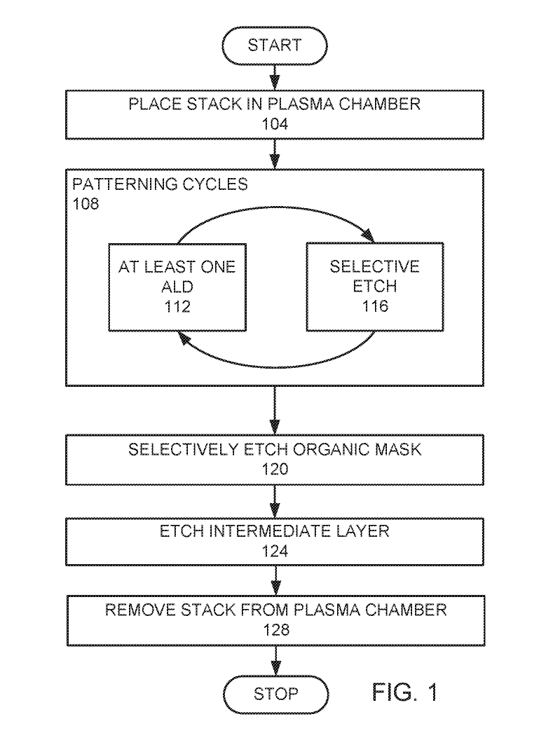

To facilitate understanding, FIG. 1 is a high level flow chart of an embodiment. A stack with a patterned mask over an intermediate layer over a substrate is placed on a substrate support in a plasma chamber (step 104). A plurality of patterning cycles is provided to create an ALD layer (step 108). Each patterning cycle comprises at least one cycle of conducting an atomic layer deposition over the mask features (step 112) to create the ALD layer and a selective etching of the top portions of the ALD layer (step 116). The patterned mask is selectively etched with respect to the ALD layer (step 120). The ALD layer is used as an etch mask for etching the intermediate layer below the ALD layer (step 124). The stack is removed from the substrate support in the plasma chamber (step 128).

### Example

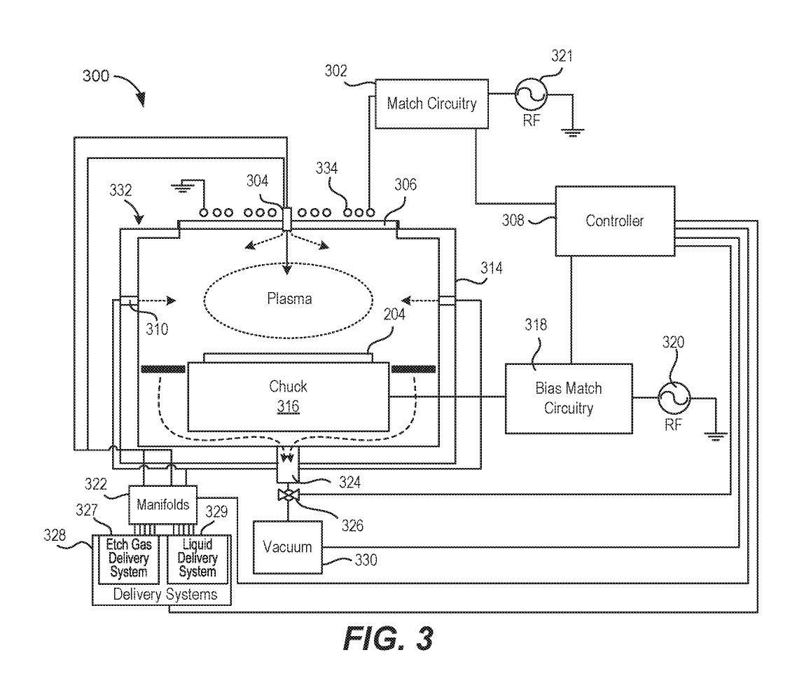

FIG. 3 schematically illustrates an example of a plasma processing system 300 which may be used to perform the process of an embodiment. The system includes a chamber 332 that includes a chamber body 314, a chuck 316, and a dielectric window 306. The chamber 332 includes a processing region and the dielectric window 306 is disposed over the processing region. The chuck 316 can be an electrostatic chuck for supporting the substrate 204 and is disposed in the chamber below the processing region. A TCP coil 334 is disposed over the dielectric window 306 and is connected to match circuitry 302, which is connected to a plasma RF generator 321.

The system includes a bias RF generator 320, which can be defined from one or more generators. If multiple generators are provided, different frequencies can be used to achieve various tuning characteristics. A bias match 318 is coupled between the RF generators 320 and a conductive plate of the assembly that defines the chuck 316. The chuck 316 also includes electrostatic electrodes to enable the chucking and dechucking of the wafer. Broadly, a filter and a DC clamp power supply can be provided. Other control systems for lifting the wafer off of the chuck 316 can also be provided.

A first gas injector 304 provides two different channels to inject two separate streams of process gases or liquid precursor (in vapor form) to the chamber from the top of the chamber. It should be appreciated that multiple gas supplies may be provided for supplying different gases to the chamber for various types of operations, such as process operations on wafers, waferless auto-cleaning (WAC) operations, and other operations. A second gas injector 310 provides another gas stream that enters the chamber through the side instead of from the top.

Delivery systems 328 includes, in one embodiment, an etch gas delivery system 327 and a liquid delivery system 329. Manifolds 322 are used for selecting, switching, and/or mixing outputs from the respective delivery systems. As will be described in more detail below, the etch gas delivery system is configured to output etchant gases that are optimized to etch one or more layers of materials of a substrate. The manifolds 322 are further optimized, in response to control from the controller 308, to perform atomic layer deposition (ALD). A vacuum pump 330 is connected to the plasma chamber 332 to enable vacuum pressure control and removal of gaseous byproducts from the chamber during operational plasma processing. A valve 326 is disposed between exhaust 324 and the vacuum pump 330 to control the amount of vacuum suction being applied to the chamber.

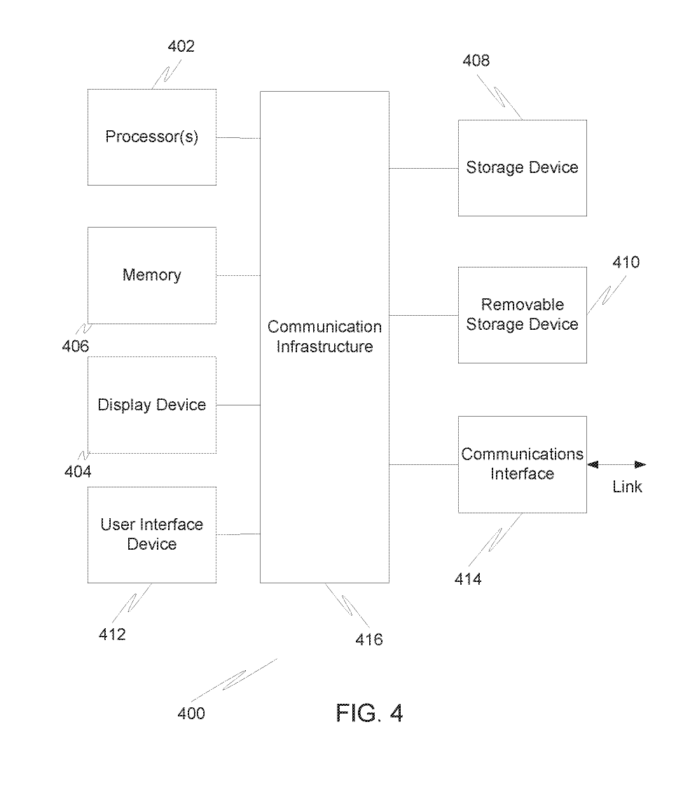

FIG. 4 is a high level block diagram showing a computer system 400, which is suitable for implementing a controller 308 used in an embodiment. The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

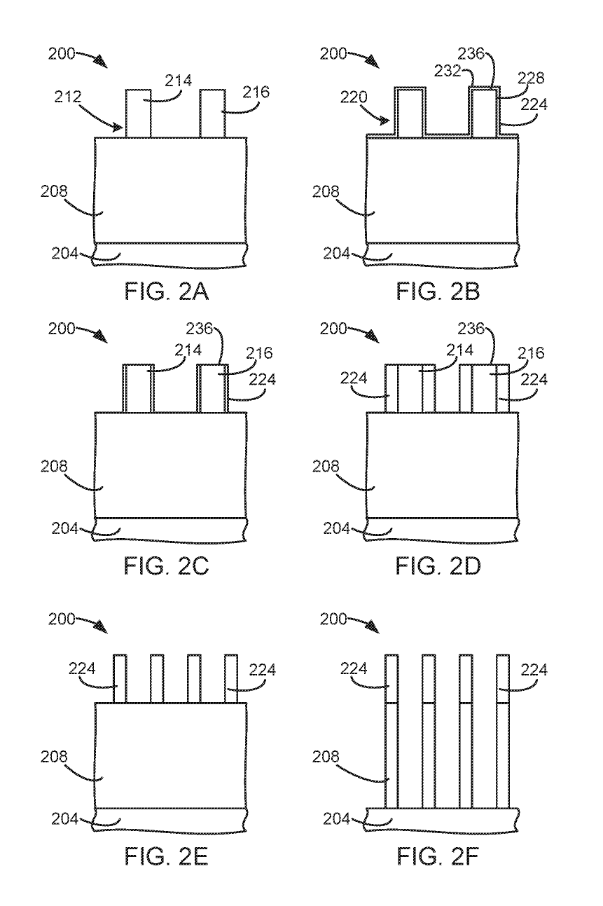

In an example of an implementation of the embodiment, a stack is placed on a substrate support in a plasma chamber (step 104). FIG. 2A is a cross sectional view of a stack 200 with a substrate 204 disposed below an intermediate layer 208, disposed below a patterned mask 212. In this example, the patterned mask 212 is an organic patterned mask, such as a photoresist mask, with a first mask feature 214 and a second mask feature 216. One or more layers (not shown) may be disposed between the substrate 204 and the intermediate layer 208. One or more layers (not shown), such as an antireflective coating, may also be disposed between the intermediate layer 208 and the patterned mask 212.

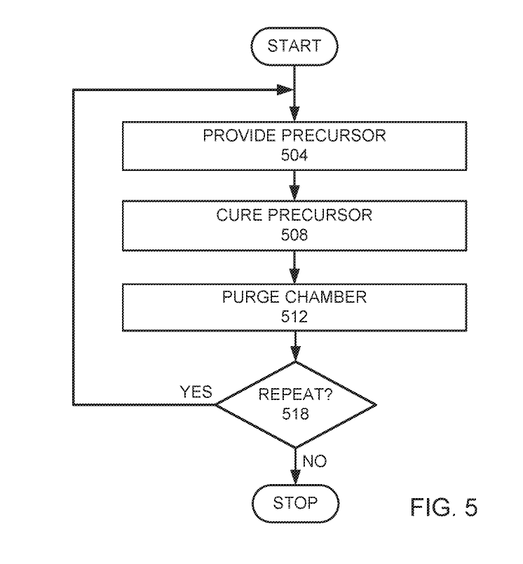

A plurality of patterning cycles is provided (step 108). Each patterning cycle comprises at least one cycle of conducting an ALD over the mask features to create an ALD layer (step 112) and a selective etching of the tops of the ALD layer (step 116). FIG. 5 is a more detailed flow chart of a cycle of conducting an ALD over the mask features (steps 112). A precursor is provided to the mask features (step 504). In this embodiment, a liquid silicon containing precursor is vaporized and delivered in vapor form into the chamber 332, to dose the mask features 214, 216 to saturation, forming a layer of precursor over the mask features 214, 216. Once the mask features 214, 216 are dosed with the precursor, the delivery of the vapor is stopped by the manifolds 322. The precursor is then cured (step 508), which in an embodiment is accomplished by subjecting the stack 200 to a flash process, which includes powering the chamber 332 using the RF generators 321 and 320 and delivering oxygen (O₂) to the chamber 332. This flash process is referred to as an “O₂ flash” operation, as the time during which RF power is delivered is relatively fast, e.g., between about 0.5 second and about 4 seconds. The O₂ flash forms a silicon oxide monolayer from the monolayer of the silicon containing precursor. Once the O₂ flash operation is completed, the chamber 332 is purged (step 512). The cycle may then be repeated (step 518)

In an embodiment of the ALD cycle, any suitable liquid precursor capable of forming a conformal atomic layer can be used. By way of non-limiting example, the liquid precursor can have a composition of the general type C(x)H(y)N(z)O(a)Si(b). In some embodiments, the liquid precursor has one of the following compositions: C₆H₁₉N₃Si, C₈H₂₂N₂Si, C₉H₂₃NO₃Si, and C₁₂H₂₈O₄Si. In this example, the providing of the precursor is plasmaless. The precursor has a silicon function group, which forms a monolayer on the structures, since the precursor does not attach to another precursor.

FIG. 2B is a cross sectional view of the stack 200 after five (5) ALD cycles, which forms an ALD layer 220 over the patterned mask 212. The ALD layer 220 has sidewalls 224 formed over sidewalls 228 of the mask features 214, 216 and top portions 232 formed over the respective tops 236 of the mask features 214, 216. Because the ALD layer 220 was formed cyclically from a plurality of thinner ALD layers, the ALD layer 220 is squarer, providing vertical sidewalls.

Once a number of ALD cycles are processed, a selective etch is provided that selectively etches the top portions 232 of the ALD layer 220 with respect to sidewalls 224 of the ALD layer 220 (step 116). Since in this embodiment, the top portions 232 of the ALD layer 220 are horizontal and the sidewalls 224 are vertical, the selective etch selectively etches horizontal layers at the top with respect to vertical layers. An example of an etch for providing a selective etch would be a fluorine based highly ion assisted etch.

FIG. 2C is a cross sectional view of the stack 200 after ALD layer 220 has been selectively etched (step 116). The top portions of the ALD layer 220 have been etched away. The sidewalls 224 of the ALD layer 220 remain. The respective tops 236 of the first mask feature 214 and the second mask feature 216 are exposed. In this example, the ALD layer 220 forming a horizontal surface over the intermediate layer 208 is also etched away.

The patterning cycles (step 108) is repeated a plurality of times repeating the ALD cycles (step 112) and the selective etch (step 116) a plurality of times.

FIG. 2D is a cross sectional view of the stack 200 after the patterning cycles (step 108) have been repeated a plurality of times. The sidewalls 224 have been widened/thickened. The vertical sidewall shape and square corners have been maintained, by applying only a thin monolayer during each ALD cycle and providing several cycles of selective etching. In addition, the respective tops 236 of the first mask feature 214 and the second mask feature 216 are exposed.

The patterned mask 212 is selectively etched with respect to the ALD layer 220 (step 120). An example for selectively etching the patterned mask 212 with respect to the sidewalls of the ALD layer 220 uses oxygen based low ion plasma for etching. FIG. 2E is a cross sectional view of the stack 200 after patterned mask 212 has been removed. The sidewalls 224 remain as new mask features. The density of the new mask features is twice the density of the original mask features 214, 216.

An etch process is provided to etch the intermediate layer 208 with respect to the sidewalls 224 of the ALD layer 220. FIG. 2F is a schematic cross sectional view of the stack 200, after the intermediate layer 208 is etched with respect to the sidewalls 224 to form etch features. In various embodiments, other steps may be used to further process the stack 200. After the stack 200 is processed, the stack 200 is removed from the substrate support and the plasma chamber (step 128).

This embodiment is able to provide etched features with double the density of the features compared to the original photoresist mask. The use of ALD and selective etching forms square features with vertical sidewalls, which reduce defects.

In different embodiments, after the patterned mask is selectively etched, patterning cycles may be used to form sidewalls on the remaining sidewalls out of a different material than the remaining sidewalls. In various embodiments, the patterned mask is a carbon containing mask, such as photoresist. In the above example, the precursor was a silicon containing polymer to bind to the patterned mask, to form the self limiting silicon containing monolayer. In this example, the silicon containing polymer is a polymer with a silicon functional group. In various embodiments, the precursor may be a liquid, a vapor of a liquid, or a gas. Such precursors are generally described as being in fluid form. The curing of the precursor forms the silicon containing monolayer into a silicon oxide monolayer. Subsequent layers would use the precursor to form a self limiting silicon containing monolayer over the silicon oxide containing sidewall, which is cured to add an additional monolayer of silicon oxide. In this example, the precursor is able to form a monolayer on different types of material, such as a silicon containing material or an organic material. In an embodiment, a silicon nitride ALD layer is formed over the silicon oxide deposition. Such a process may be used to double the pattern again, when the silicon oxide is selectively etched with respect to the silicon nitride. Because various embodiments provide vertical sidewalls with square tops, the feature detail is improved.

In various embodiments, a plurality of ALD cycles are performed before each selective etch. In more preferred embodiments, at least five (5) ALD cycles are performed before each selective etch. In more preferred embodiments, between five (5) and twenty (20) ALD cycles are performed before each selective etch. In various embodiments, at least five (5) patterning cycles are completed, so that at least five (5) selective etches are provided. In other embodiments, at least twenty (20) patterning cycles are completed. In other embodiments, at least one hundred (100) patterning cycles are completed. In some embodiments, between one (1) and thirty (30) patterning cycles are completed.

In various embodiments, the curing of the monolayer may be done by applying radio frequency (RF) power to the plasma chamber along with an oxygen gas to perform a plasma flash process (or O₂ plasma cure), the plasma flash process being processed for a period of time that is between about 0.2 second and about 4 seconds, and the RF power is applied at a power level that is between about 200 watts and about 3,000 watts. The O₂ plasma cure converts the Si containing precursor into SiO₂.

In various embodiments, different recipes may be used to selectively etch the top portions of the ALD layer with respect to sidewalls of the ALD layer. Spacer etch recipes may be used to accomplish this in different embodiments.

The above embodiments are performed in situ in a single chamber, without moving the chuck or removing the stack from the chuck. Such embodiments provide faster and less expensive throughput. In addition, thinner layers may be applied, since the in situ process allows for a greater number of cycles, which allows for the improved feature shapes.

While this disclosure has been described in terms of several preferred embodiments, there are alterations, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

1. A method for in-situ patterning a stack having a patterned mask with mask features including sidewalls and tops, comprising:
providing a plurality of patterning cycles in a plasma chamber, wherein each patterning cycle comprises:
at least one (1) cycle of conducting an atomic layer deposition (ALD) over the mask features to create an ALD layer, wherein the ALD layer includes sidewalls over the sidewalls of the mask features and top portions over the tops of the mask features; and
selectively etching the top portions of the ALD layer with respect to the sidewalls of the ALD layer, wherein each successive cycle creates a second ALD layer that is of a same material a first ALD layer, wherein the second ALD layer is in contact with the first ALD layer.

2. The method, as recited in claim 1, wherein the plurality of patterning cycles includes at least five (5) cycles.

3. The method, as recited in claim 1, wherein the ALD deposits a monolayer to create the ALD layer.

4. The method, as recited in claim 1, further comprising selectively etching the patterned mask with respect to the ALD layer.

5. The method, as recited in claim 1, wherein the ALD layer is made of a silicon containing material.

6. The method, as recited in claim 1, wherein the patterned mask is made of a carbon containing material.

7. The method, as recited in claim 1, wherein the ALD layer is made of a silicon oxide containing material.

8. The method, as recited in claim 1, wherein the selectively etching top portions of the ALD layer with respect to sidewalls of the ALD layer exposes the tops of the of the mask features.

9. The method, as recited in claim 1, wherein the selectively etching top portions of the ALD layer with respect to sidewalls of the ALD layer uses a spacer etch.

10. The method, as recited in claim 1, wherein each cycle of the at least one (1) cycle of conducting an ALD over the mask features comprises:
introducing a precursor vapor into the plasma chamber to deposit a layer of precursor over the mask features; and
curing the layer of precursor over the mask features to form a monolayer as part of the ALD layer.

11. The method, as recited in claim 10, wherein the curing the layer of precursor comprises applying radio frequency (RF) power to the plasma chamber along with an oxygen gas to perform a plasma flash process, the plasma flash process being conducted for a period of time that is between about 0.5 second and about 4 seconds, and the RF power is applied at a power level that is between about 200 watts and about 3,000 watts.

12. The method, as recited in claim 1, wherein each cycle of the at least one (1) cycle of conducting an atomic layer deposition over the mask features comprises:
introducing a silicon containing precursor into the plasma chamber to deposit a self limiting layer of silicon containing precursor over the mask features; and
curing the self limiting layer of silicon containing precursor over the mask features with an oxygen containing plasma to form a silicon oxide monolayer over the mask features.

13. The method, as recited in claim 12, wherein the silicon containing precursor is a silicon containing polymer.

14. The method, as recited in claim 12, wherein the silicon containing precursor is a polymer with a silicon functional group.

15. The method, as recited in claim 12, wherein the introducing the silicon containing precursor is plasmaless.

16. The method, as recited in claim 1, further comprising:
selectively etching the patterned mask with respect to the ALD layer; and
etching an intermediate layer below the ALD layer using the ALD layer as an etch mask.

17. The method, as recited in claim 1, wherein each patterning cycle comprises five (5) cycles of conducting an ALD over the mask features, and wherein the plurality of patterning cycles comprises at least five (5) cycles.
